(19) United States
(12) Patent Application Publication
(10) Pub. No.: US 2005/0180482 A1
(43) Pub. Date: Aug. 18, 2005

(54) Very low cost surface emitting laser diode arrays

(76) Inventors: Mark L. Osowski, Tujunga, CA (US); Jeffrey E. Ungar, Valley Village, CA (US)

Correspondence Address: IRELL & MANELLA LLP, 840 NEWPORT CENTER DRIVE, SUITE 400, NEWPORT BEACH, CA, 92660, US

(21) Appl. No.: 11/042,759

(22) Filed: Jan. 24, 2005

Related U.S. Application Data
(60) Provisional application No. 60/538,538, filed on Jan. 23, 2004.

(51) Int. Cl. H01S 5/00

(52) U.S. Cl. 372/50.124

(57) ABSTRACT

An array of semiconductor lasers on a single semiconductive die. The die includes a plurality of laser stripes optically coupled to a reflective surface. The laser stripes generate a plurality of laser beams traveling in a direction essentially parallel to a top surface of the die. The reflective surface redirects the laser beams to emit in a direction essentially perpendicular to the top surface. Alternatively, the reflective surface may redirect the laser beams to emit from a bottom surface of the die. The reflective surface can be formed by etching a vicinally oriented III-V semiconductive die so that the reflecting surface extends along a (111)A crystalline plane of the die.

### CROSS REFERENCE TO RELATED APPLICATIONS

This application is a continuation in part of application Ser. No. 264,534 filed on Oct. 3, 2002, pending, and claims priority to provisional Application No. 60/538,538, filed on Jan. 23, 2004.

### BACKGROUND OF THE INVENTION

1. Field of the Invention

The subject matter disclosed generally relates to the field of semiconductor lasers.

2. Background Information

Semiconductor laser diode arrays are efficient and reliable sources of high power coherent light for various applications including pumping of solid-state lasers, dermatology and materials processing. Arrays of individually addressed lasers are also used for data communications.

High power laser arrays are typically fabricated by combining a plurality of laser “bars”. Each laser bar consists of a single semiconductor chip incorporating a plurality (typically 20) of edge-emitting laser stripes. Each laser bar is mounted on its own heat sink or thermal cooler, and a number of such assemblies are combined into either a vertical or a horizontal stack to form the complete high power array.

Arrays using edge-emitting technology suffer from drawbacks that sharply limit their applications. In particular, large arrays are costly to manufacture because each laser bar in the stack must be cleaved, coated, tested and mounted individually and then assembled. These operations require separating the individual laser bar from the parent wafer, because edge-emitting lasers require a cleaved, reflective laser facet for operation.

High power water-cooled multi-layer stacks are also fragile and unreliable because they require micro-channel water coolers which are easily clogged and are vulnerable to water leaks at o-ring seals.

Furthermore, the multi-layer construction of these arrays makes it difficult to maintain accurate positional alignment between bars as well as external focusing optics, which degrades the optical quality of the produced laser beam.

Surface emitting laser diodes do not require a cleaved laser facet, and can be fabricated and tested at wafer level at low cost. A single die incorporating a large number of surface-emitting diodes could be used to make a rugged, low cost laser array requiring only a single cooler and with excellent alignment between individual lasers. Unfortunately, the commercial surface-emitting technology known as Vertical Cavity Surface Emitting Lasers (VCSEL) diodes have very high thermal and electrical impedance which results in poor output power and low efficiency.

Attempts have been made to integrate in-plane laser diodes with dry-etched deflection mirrors to create low-cost surface-emitting lasers and arrays. Unfortunately, the fabrication yield, angular accuracy and optical smoothness of mirrors made by these techniques were insufficient for commercial application.

### BRIEF SUMMARY OF THE INVENTION

An array of semiconductor lasers that includes one or more reflective surfaces optically coupled to a plurality of laser stripes. The reflective surface is located along a (111)A crystalline plane of the die.

### BRIEF DESCRIPTION OF THE DRAWINGS

FIG. 1 is an illustration showing a perspective view of an array of semiconductor lasers;

FIG. 2 is an illustration showing a side sectional view of a semiconductor laser;

FIG. 3 is an illustration showing a perspective view of a compound semiconductor wafer with an etched groove;

FIG. 4 is an illustration of an enlarged cross sectional view of a slot similar to FIG. 3 but with a vicinally oriented substrate;

FIG. 5 is an illustration showing a side sectional view of alternate embodiment with light emitting regions placed adjacent to a heat sink and a reflective surface that reflects light through the substrate of a die.

### DETAILED DESCRIPTION

Disclosed is an array of semiconductor lasers on a single semiconductive die. The die includes a plurality of laser stripes optically coupled to a reflective surface. The laser stripes generate a plurality of laser beams traveling in a direction essentially parallel to a top surface of the die. The reflective surface redirects the laser beams to emit in a direction essentially perpendicular to the top surface. Alternatively, the reflective surface may redirect the laser beams to emit from a bottom surface of the die. The reflective surface can be formed by etching a vicinally oriented III-V semiconductive die so that the reflecting surface extends along a (111)A crystalline plane of the die.

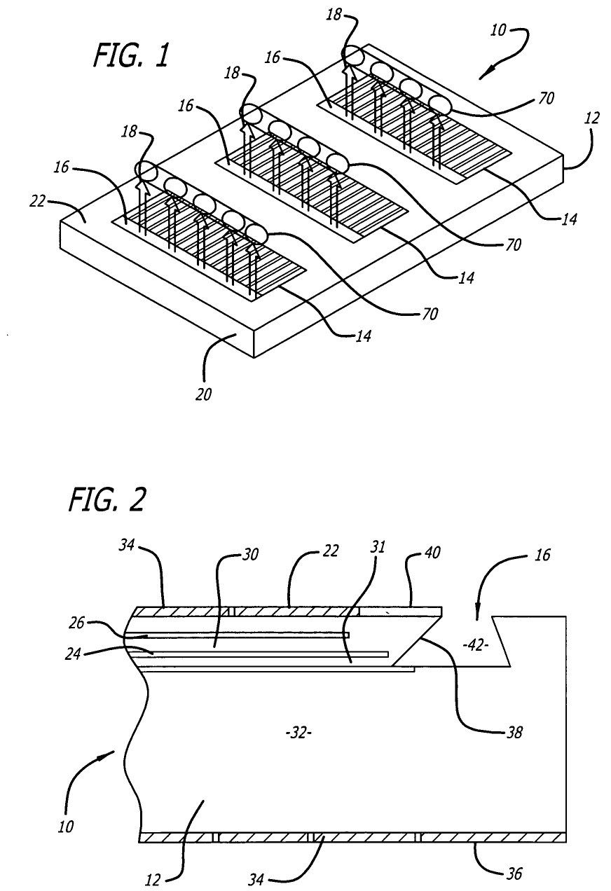

FIGS. 1 and 2 refer specifically to an embodiment where the beam emits from a top surface, but by reversing the inclination of the reflecting surface, the beam can emit from the bottom surface, if so desired. In the event that the substrate is opaque to the generated laser light, the substrate material located directly below the deflection mirror can be chemically removed by processes well known in the art. Any reference to a “surface” that emits a beam will include the top or bottom surfaces of the die.

Referring to the drawings more particularly by reference numbers, FIG. 1 shows an array of semiconductor lasers 10. The semiconductor laser 10 is fabricated as a semiconductive die 12 that contains a plurality of laser stripes 14 and one or more reflective elements 16. There is typically a reflective element 16 associated with a group of laser stripes 14. The laser strips 14 generate a plurality of laser beams 18 that travel toward an edge 20 of the die 12. The reflective element 16 reflects the laser beam 18 so that the beam 18 is emitted from a top surface 22 of the die 12.

As shown in FIG. 2, each laser stripe 14 includes a gain layer 24 and a diffraction grating feedback layer 26. The gain layer 24 is located between a P-type layer 30 and a N-type layer 31 to provide the optical gain required for oscillation. Electrical contacts 34 may be located at the top surface 22 and a bottom surface 36 of the die 12. The contacts 34 are connected to a source of electrical power that induces a migration of holes and electrons from the layers 31 and 30 to the active layer 24. The holes and electrons recombine and emit photons.

The diffraction grating feedback layer 26, which may be composed of a semiconductor alloy differing in refractive index from the P-type layer 30, may be corrugated with a period satisfying the Bragg condition for the desired frequency of oscillation. Layer 26 may extend along the entire length of the laser, in which case it forms a distributed feedback laser, or it may extend over part of the length, in which case it forms a distributed Bragg reflector laser.

Each reflective element 16 may include a reflective surface 38 that can reflect the laser beams through an exit facet 40 in the top surface 22 of the die 12. The facet 40 may have an anti-reflection coating, or may have multi-layer stacks, either epitaxial or deposited, to enhance the reflectivity. The reflective surface 38 is formed at a 45 degree angle relative to the top surface 22. The 45 degree angle will deflect the laser beam 90 degrees by total-internal-reflection so that the laser exits the die 12 perpendicular to the top surface 22. The reflective surface 38 may extend along a groove 42 in the die 12.

The semiconductive die 12 can be epitaxially grown on an indium-phosphide, gallium-arsenide or other III-V semiconducting substrate. The (111)A crystalline plane of these and other III-V semiconductors are more thermodynamically stable than planes of different direction. Consequently, chemically etching such materials leaves an exposed surface along the (111)A crystalline plane.

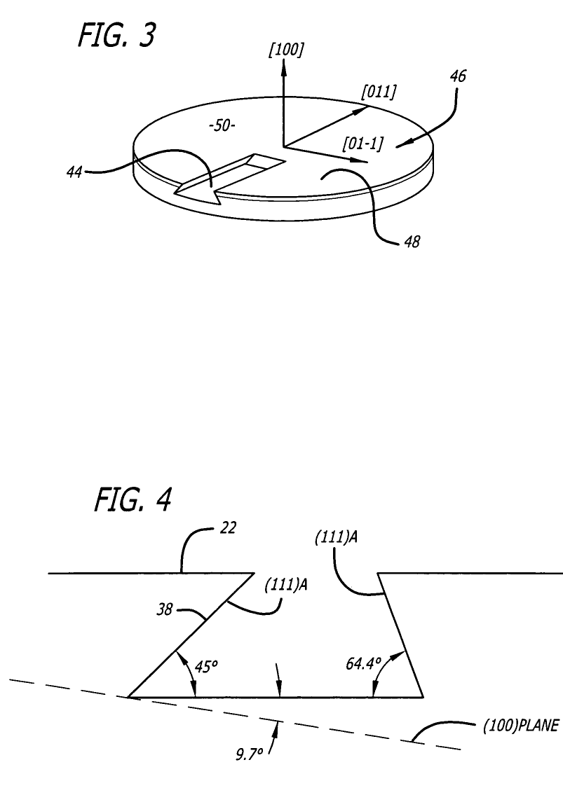

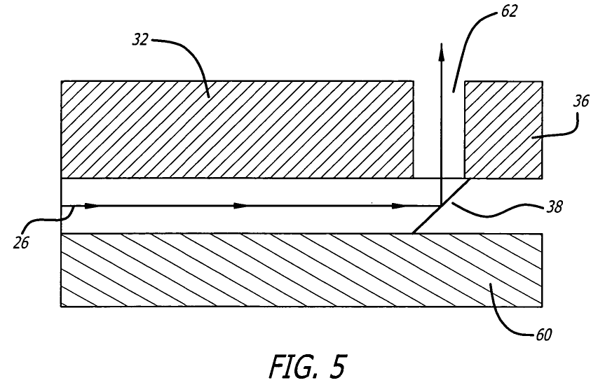

As shown in FIG. 3, if surface 50 of a conventionally(100) oriented III-V semiconducting wafer 46 is protected by chemically resistant mask 48, except for the region of exposed [011] oriented slot 44, and is typically etched with a chlorine or bromine based etchant, an overhanging “dove-tail” shaped groove is formed. The resulting groove's sidewalls are (111)A surfaces, which are inclined by 54.7 degrees to the surface, and are not suitable for use as a 45 degree deflection mirror. If, as shown in FIG. 4, a vicinally oriented substrate 22 that is inclined by 9.7 degrees from the (100) direction towards the [01-1] direction is used instead of a conventional (100) oriented substrate, the resulting (111)A sidewall 38 is inclined to the surface by 45 degrees. This sidewall is suitable for use as a 90 degree deflection mirror.

The result is a repeatable process to form a 45 degree reflective surface within the die. Additionally, the etching process creates a relatively smooth reflective surface 38. The reflective surfaces 38 are typically formed after fabrication of the laser stripes 14.

Typically, a large number of laser dice 12 will be fabricated in parallel on a single wafer, which is then cut into arrays of laser diodes.

FIG. 5 shows an alternate embodiment wherein the reflective element 16′ redirects the laser beams through the substrate of the die. This allows a heat sink 60 to be attached directly to the junction area of the die. The junction area is the area of the die that generates the largest amount of heat. Attaching the heat sink 60 directly to this area improves the thermal efficiency of removing heat from the laser diode array. If the substrate is not transparent to the light beam an opening 62 may be formed therein to allow passage of the light from the bottom surface of the die. By way of example, the opening 62 may be etched from the substrate 32.

By way of example the laser stripes may be connected in an electrically parallel arrangement. It may be advantageous under certain circumstances to pump some or all of the stripes, or stripe sections in series, in which case the sections can be mechanically separated by a process such as diamond sawing or chemical etching, and then mounting the sections on a suitably patterned heat sink.

It is often advantageous to collimate the output of a high power array with an array of collimating lenses 20. Effective collimation requires accurate alignment of each stripe to an associated collimating lens 20. The present invention permits this collimation to be performed in one-step, by mating the array to a matching monolithic array of collimation lenses 20. This contrasts to conventional arrays, where the mechanical registration between separate rows is very inaccurate.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. In particular, an essentially equivalent laser could be made if the conductivity types of P-doped and N-doped layers are reversed, if the positions of active layer 28 and distributed feedback layers 26 are reversed.

1. An array of semiconductor lasers, comprising:
a semiconductive die that includes;
a plurality of laser stripes; and,
a reflective surface optically coupled to said laser stripes and located along a (111)A crystalline plane of said semiconductive die.

2. The array of claim 1, wherein said semiconductive die is fabricated from III-V compound semiconducting crystals.

3. The array of claim 1, wherein a surface of said semiconductive die is located at an angle relative to a (100) crystalline plane of said semiconductive die.

4. The array of claim 1, wherein said reflective surface is located at a 45 degree angle relative to a surface of said semiconductor die.

5. The array of claim 1, further comprising a heat sink that is attached to said semiconductive die and said reflective surface reflects light through a substrate of said semiconductive die.

6. The array of claim 1, wherein said reflective surface is located along a groove that extends across a portion of a surface of said semiconductive die.

7. The array of claim 1, further comprising a plurality of lenses coupled to said reflective surface.

8. The array of claim 7, wherein said lenses are collimating lenses.

9. An array of semiconductor lasers, comprising:
a semiconductive die that has a surface and includes;
laser means for generating a plurality of laser beams; and,
reflection means for reflecting the laser beams so that the laser beam exits the semiconductive die from said surface.

10. The array of claim 9, wherein said semiconductive die is fabricated from a III-V semiconducting crystal.

11. The array of claim 9, wherein said surface is located at an angle relative to a (100) crystalline plane of said semiconductive die.

12. The array of claim 9, wherein said reflection means includes a reflective surface that is located at a 45 degree angle relative said surface of said semiconductor die.

13. The array of claim 9, further comprising a heat sink that is attached to said semiconductive die and said reflection means reflects light through a substrate of said semiconductive die.

14. The array of claim 9, wherein said reflection means includes a reflective surface that is located along a groove which extends across a portion of said surface of said semiconductive die.

15. The array of claim 9, further comprising lens means coupled to said reflection means.

16. The array of claim 15, wherein said lens means includes at least one collimating lens.

17. A method for operating an array of semiconductor lasers, comprising:
generating a plurality of laser beams; and,
reflecting the laser beams from a reflective surface of a semiconductive die 90 degrees so that the laser beams exit a surface of the semiconductor die, the reflective surface being located along a (111)A crystalline plane of the semiconductive die.

18. The method of claim 17, wherein the laser beams are reflected from a top surface of the semiconductive die.

19. The method of claim 17, wherein the laser beams are reflected through a substrate of the semiconductive die.

20. A method for fabricating an array of semiconductor lasers, comprising:
forming a plurality of laser stripes on a semiconductive wafer;
forming a mask on a portion of a semiconductive wafer such that there is an unmasked portion of the semiconductive wafer;
etching the unmasked portion of the semiconductive wafer to create a reflective surface that extends along a (111)A crystalline plane of the semiconductive wafer; and,
cutting a semiconductive die that contains at least two laser stripes and said reflective surface from the semiconductive wafer.

21. The method of claim 20, wherein the semiconductive wafer is fabricated with III-V compound semiconducting crystals.

22. The method of claim 20, further comprising cutting the semiconductive wafer so that a surface of the semiconductive wafer is located at an angle relative to a (100) crystalline plane of the semiconductive wafer.

23. The method of claim 20, further comprising attaching a heat sink to the semiconductive die.

24. The method of claim 23, further comprising forming an opening in a substrate of the semiconductive die.

25. The method of claim 20, further comprising coupling a plurality of lenses to the reflective surface.

26. The method of claim 25, wherein the lenses are collimating.
